(19) United States
(12) Patent Application Publication
(10) Pub. No.: US 2016/0090667 A1
(43) Pub. Date: Mar. 31, 2016

(54) FEED SYSTEM INCLUDING A DEADSORPTION UNIT AND A TUBE AND A METHOD OF USING THE SAME

(71) Applicant: Saint-Gobain Ceramics & Plastics, Inc., Worcester, MA (US)

(72) Inventors: Jan J. BUZNIAK, Solon, OH (US); Charles J. GASDASKA, Shrewsbury, MA (US); John M. FRANK, Akron, OH (US)

(21) Appl. No.: 14/867,678

(22) Filed: Sep. 28, 2015

Related U.S. Application Data
(60) Provisional application No. 62/057,000, filed on Sep. 29, 2014.

(51) Int. Cl. C30B 35/00; C30B 29/20; C30B 15/00; C30B 15/34; C30B 15/02

(52) U.S. Cl. CPC C30B 35/007; C30B 15/34; C30B 15/02; C30B 15/002; C30B 29/20

(57) ABSTRACT

A feed system for a crystal growth apparatus can include a deadsorption unit and a tube. In an embodiment, the deadsorption unit can deadsorb an impurity from a material used to form a crystal. The tube can be fluidly coupled to the deadsorption unit and the crystal growth apparatus to transfer the material from a lower point to a higher point. In another embodiment, any finite number of deadsorption units may be coupled to any finite number of crystal growth apparatuses. In a further embodiment, a crystal growth system can include the feed system and a crystal growth apparatus, wherein the feed system can continuously provide crystal-forming material to the crystal growth apparatus as a crystal is being formed.

### CROSS-REFERENCE TO RELATED APPLICATIONS

The present application claims priority to U.S. Provisional Patent Application No. 62/057,000, filed Sep. 29, 2014, entitled “Feed System Including a Deadsorption Unit and a Tube”, naming as inventors Jan J. Buzniak et al., which application is incorporated by reference herein in its entirety.

### FIELD OF THE DISCLOSURE

The present disclosure is directed to feed systems that include a deadsorption unit and a tube.

### BACKGROUND

A melt can be used in growing a crystal that is to be transparent. As haze increases, the crystal may scatter light, and in extreme cases can make the crystal more translucent as opposed to transparent. Improvements in crystal growth rates while maintaining acceptable haze levels are desired.

### BRIEF DESCRIPTION OF THE DRAWINGS

Embodiments are illustrated by way of example and are not limited in the accompanying figures.

FIG. 1 includes an illustration of a process schematic drawing of a crystal growth system including a feed system and a crystal growth apparatus in accordance with an embodiment.

FIG. 2 includes an illustration of a cutaway view of a deadsorption unit.

FIG. 3 includes an illustration of a top view of a particle distributor within the deadsorption unit of FIG. 2.

FIG. 4 includes an illustration of a top view of an alternative particle distributor.

FIG. 5 includes an illustration of a perspective view of a gas distributor within the deadsorption unit of FIG. 2.

FIG. 6 includes an illustration of a cutaway view of an alternative deadsorption unit.

FIG. 7 includes an illustration of a cutaway view of a portion of a crystal growing apparatus.

FIGS. 8 to 10 include illustrations of alternative embodiments having different ratios and associations between deadsorption units and crystal growth apparatuses.

FIG. 11 includes an illustration of an embodiment with an intermediate container between deadsorption units and crystal growth apparatuses.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings.

As used herein, the terms “comprises,” “comprising,” “includes,” “including,” “has,” “having,” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

The use of “a” or “an” is employed to describe elements and components described herein. This is done merely for convenience and to give a general sense of the scope of the invention. This description should be read to include one or at least one and the singular also includes the plural, or vice versa, unless it is clear that it is meant otherwise.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the crystal growing arts.

A crystal can be formed from an initial material in which an impurity is deadsorbed before growing the crystal. In an embodiment, the initial material may be deadsorbed within a deadsorption unit and transferred to a crystal growth apparatus via a tube between the deadsorption unit and crystal growth unit. In an embodiment, the transfer can be performed using the venturi effect to allow a carrier gas, as supplied by a gas source or pulled by a vacuum, to allow the deadsorbed material and carrier gas to become a fluidized stream to allow the deadsorbed material to be transferred to a higher elevation. Many configurations of feed systems can be used to allow for a 1:1, many:1, 1:many, or many:many ratios of deadsorption units to crystal growth apparatuses.

In another aspect, a method can include deadsorbing an impurity from an initial material to form deadsorbed material that can be melted and used to form a crystal. In an embodiment, the initial material may be crushed to reduce closed porosity before deadsorption. The deadsorption helps to increase the growth rate of a crystal while maintaining an acceptable level of haze. Haze can be distinguished from microvoids, as microvoids are typically on surface to be ground off, and haze is typically through bulk. The method is particularly useful when the crystal is being formed in a continuous feed system. In a particular embodiment, a relatively constant amount of material can be maintained within the crucible. The concepts are better understood with respect to the description below in conjunction with the figures.

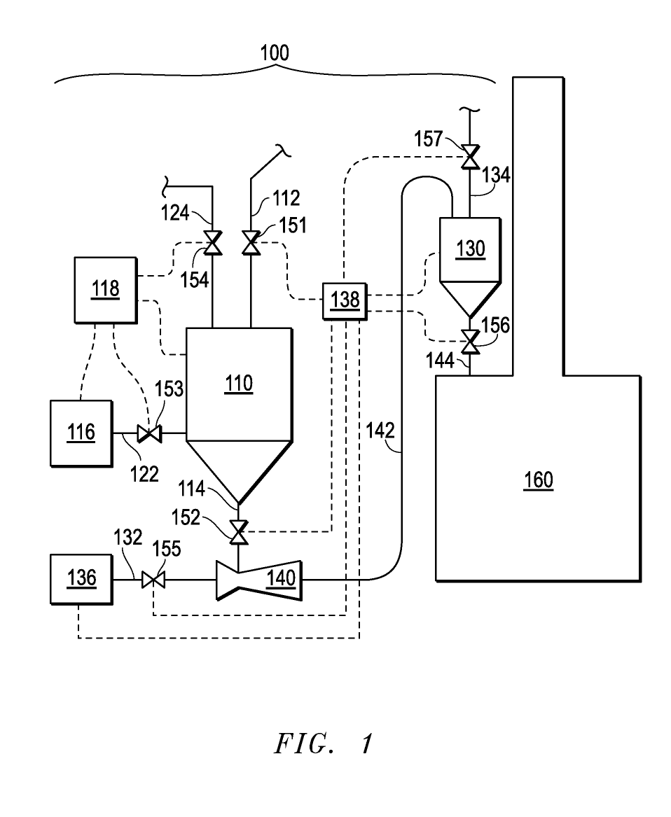

FIG. 1 includes a process schematic drawing of a crystal growth system that includes a feed system 100 and a crystal growth apparatus 160. In the process schematic drawing, solid lines represent lines where gases, liquids and solids flow, and dashed lines represent signal lines for sending control signals or receiving data from sensors and other instruments within the system. The components within the feed system 100 are described before describing the operation of the feed system 100.

The feed system 100 includes a deadsorption unit 110 that is coupled to a material inlet line 112, a material outlet line 114, a deadsorption gas inlet line 122, and a deadsorption gas outlet line 124. The deadsorption gas outlet line 124 may also be a vacuum port for the deadsorption unit 110 or the deadsorption unit 110 may have a vacuum port separate from the deadsorption gas outlet line 124. In another embodiment, the deadsorption may not operate under vacuum, and the deadsorption gas outlet line can be coupled to an electrostatic precipitator, a scrubber, or the like. A deadsorption gas source 116 is coupled to the deadsorption gas inlet line 122. In an embodiment, a heater can be part of the deadsorption gas source 116 or may be used on the deadsorption gas inlet line 122 to heat the deadsorption gas, if needed or desired. A deadsorption controller 118 is coupled to the deadsorption unit 110, the deadsorption gas source, and valves 153 and 154.

The feed system 100 further includes a carrier gas source 136, a venturi device 140, and a particle separator 130. In the embodiment illustrated in FIG. 1, the venturi device 140 is coupled to a carrier gas inlet line 132 that is coupled to a carrier gas source 136, the material outlet line 114, and a tube 142. The tube 142 may include a liner if needed or desired. The venturi device 140 can be a venturi valve, a venturi eductor, or another suitable device to generate a fluidized stream. The particle separator 130 is coupled to the tube 142, a carrier gas outlet line 134, and a particle outlet line 144. In an embodiment, a heater can be part of the carrier gas source 136 or may be used on the carrier gas inlet line 132 to heat the carrier gas, if needed or desired. In a further embodiment, a heater can be part of the particle separator 130, if needed or desired. At normal operating conditions, the initial and deadsorbed materials are chemically inert with all components within the feed system 100 that such materials would contact. When plastic material is used for any of the lines 112, 114, 144, tubing 142 or its liner or any combination thereof, the plastic material may not include an inorganic filler, a colorant, or any combination thereof. Furthermore, any of the lines 112, 114, 144, the deadsorption unit 110, the venturi device 140, tube 142 or its liner, the particle separator 130, or any combination thereof can be electrically conductive to dissipate charge that may build up due to the initial or deadsorbed material moving through the feed system 100. The crystal growth apparatus 160 is coupled to the particle outlet line 144. A transfer controller 138 is coupled to the carrier gas source 136, the particle separator 130, and valves 151, 152, 155, 156, and 157.

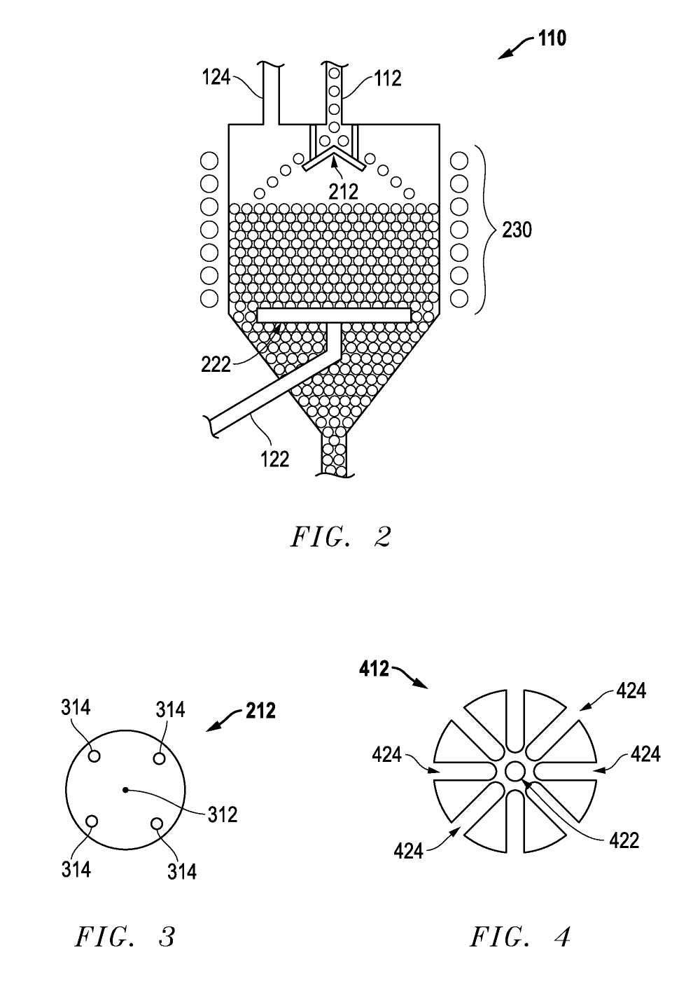

Many different designs can be used for the deadsorption unit 110. FIG. 2 includes an illustration of a cutaway view of an exemplary, non-limiting design for the deadsorption unit 110. The deadsorption unit 110 can include a particle distributor 212, a gas distributor 222, and a heater 230. In the embodiment as illustrated, the particle distributor 212 is in the form of a cone. Referring to FIG. 3, the particle distributor 212 has an apex 312, and the upper surface of the particle distributor 212 slopes away from the apex 312. The particle distributor 212 is patterned to define holes 314 so that supports can be attached to the particle distributor 212 in order to mount the particle distributor 212 in the deadsorption unit 110. In another embodiment, a different flow distributor can be used. In alternative embodiment, the flow distributor can be a flat plate instead of a cone. FIG. 4 includes an illustration of an alternative embodiment where a particle distributor 412 is in the form of a patterned plate that has a hole 422 in the center and slots 424 extending from the perimeter toward the center. Many other designs for the particle distributor may be used without departing from the scope of the appended claims. In another embodiment, no particle distributor may be used.

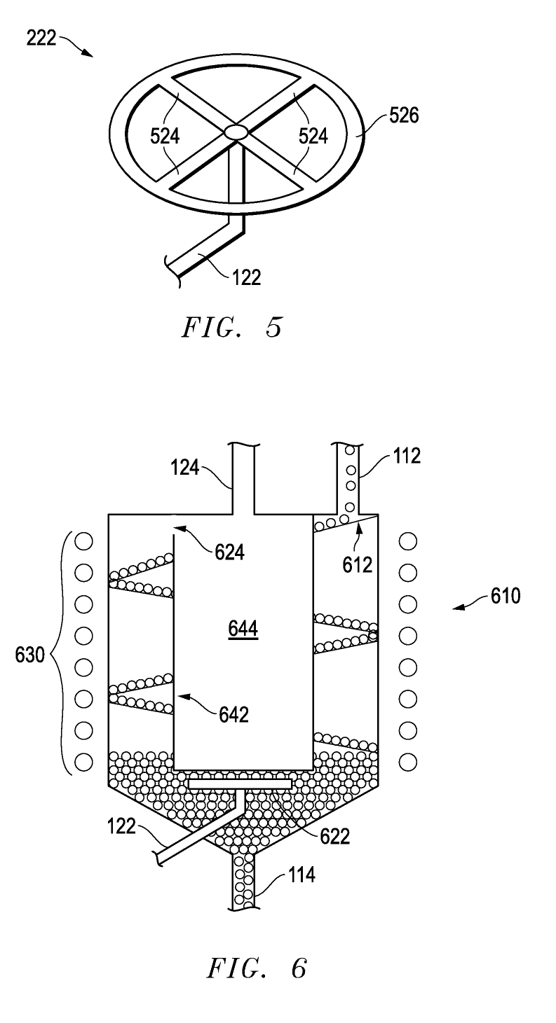

FIG. 5 includes a perspective view of the gas distributor 222. Deadsorption gas can enter the deadsorption gas inlet line 122 and reach the center of the gas distributor 222 and flow through hollow legs 524 to an outer ring 526. The hollow legs 524 and outer ring 526 can include holes to allow the deadsorbing gas to contact the material. Holes may be located along the bottom of the legs 524 and ring 526. The gas can pass through the material and exit through the deadsorption gas outlet line 124. If needed or desired, a screen or another suitable device can be used to reduce the likelihood that the material will enter the deadsorption gas outlet line 124.

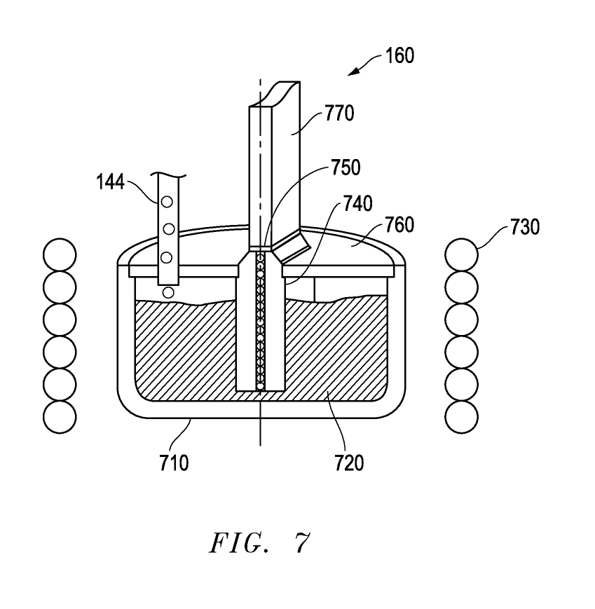

FIG. 6 includes an illustration of an alternative embodiment of a deadsorption unit 610. The deadsorption unit 610 includes a helical race 612 that is attached to an inner wall 642 that defines a central region 644. Material can enter the deadsorption unit 610 through the material inlet line 112 and travel down the helical race 612 to the bottom. Deadsorption gas can enter the deadsorption unit 610 flow in a direction up the helical race 612, counter to the material flow, flow through an opening 624 into the central region 644, and exit through the deadsorption gas outlet line 124. In a more particular embodiment, the helical race 612 may include openings through the thickness of the race to allow more of the deadsorbing gas to pass by the material being deadsorbed. In another embodiment, more than one opening though the inner wall 642 if needed or desired. The location or size of the opening(s) through the inner wall 642 is selected so that the material that enters the material inlet line does not enter the central region 644. The deadsorption unit 610 can also include a heater 630 around the outside of the deadsorption chamber. In another embodiment, a heater (not illustrated) may be located within the central region in place of or in addition to the heater 630.

Still other designs for the deadsorption unit can be used. Many solid particle driers can be modified for use as deadsorption unit. For example, a conveyor drier with a crusher, such as one in FIG. 20-33 in Chemical Engineers' Handbook, 5^{th} Edition; Perry and Chilton, editors; McGraw Hill; pg. 20-31 (1973), illustrates a two-pass drier with a particle crusher between the passes. Little or no O₂ or H₂O should be allowed to enter the deadsorption chamber, and therefore, the feed system may be sealed. Accordingly, a solid particle drier, such as the one in FIG. 20-33 may be modified to be a sealed system. After reading this specification, skilled artisans will appreciate that the deadsorption units as illustrated and described are merely exemplary and not limiting.

Referring to FIG. 1, the particle separator 130 receives the fluidized stream and separates the carrier gas from the material. As the fluidized stream travels from the venturi device 140 to the particle separator 130, small particles may be generated as material within the fluidized stream contacts the tube 142 or fittings along the flow path and may be a contaminant if they were to enter the crystal growth apparatus 160. Such particles are significantly smaller than the particles of the deadsorbed material from the deadsorption unit 110. These smaller particles may be separated from the carrier gas in the particle separator 130. A screen or another mechanical separator may be located within the particle separator, so the smaller particles can be removed from the larger particles of the deadsorbed material. Alternative, the smaller particles may be removed with the carrier gas through the carrier gas outlet line 134. A subsequent separator, an electrostatic precipitator, or a scrubber can be used to remove the smaller particles from the carrier gas.

The crystal growth apparatus 160 can be used to form crystal in the shape of a boule or a defined shape, such as a sheet, a tube, a cylinder, a fiber, or another suitable shape. The crystal growth apparatus can be a Czochralski growth apparatus, a Kyropolous growth apparatus, or a Bridgman growth apparatus, or Vertical Gradient Freeze (VGF) apparatus when the crystal will be in the form of a boule. The crystal growth apparatus can be a Stepanov growth apparatus or an edge-defined film-fed growth (EFG) apparatus when the crystal is to have a defined shape. FIG. 7 includes an illustration of a cutaway view of the crystal growth apparatus 160 that is part of an EFG apparatus. Deadsorbed material passes through an opening in a lid 760 and be received by the crucible 710. A heater 730 is used to heat to form the melt 720 that is in contact with die 740 that includes a capillary tube and an upper surface to define the shape of the crystal 770. In another embodiment (not illustrated), a greater number of tips in the die can be used to form a plurality of thin crystal sheets to improve material efficiency.

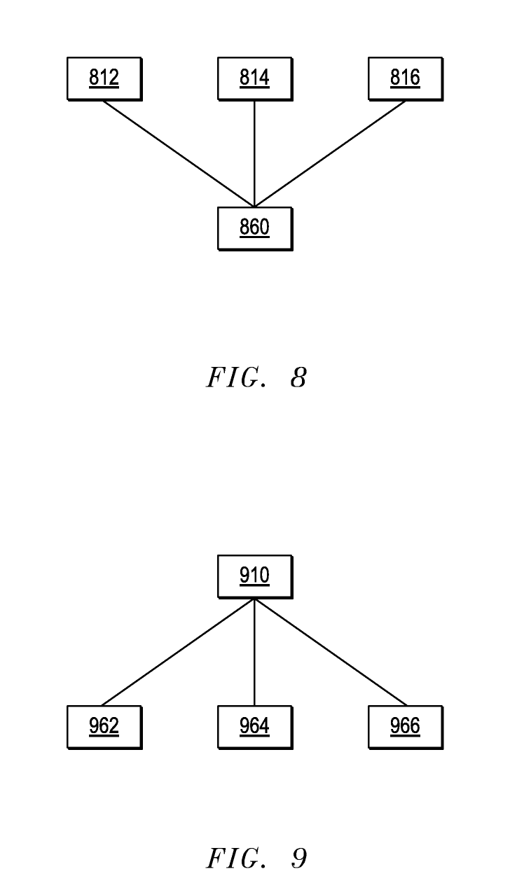

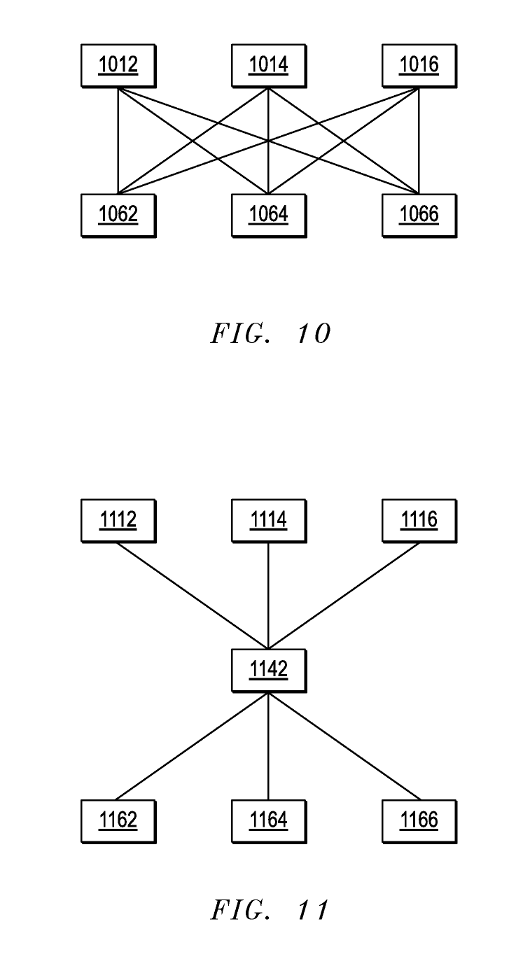

The crystal growth systems can have a variety of deadsorption unit:crystal growth apparatus ratios. The embodiments previously described have a 1:1 ratio. Other ratios can be used. In an embodiment, two or more deadsorption units can be dedicated to a single crystal growth apparatus. FIG. 8 illustrates a 3:1 ratio, where three deadsorption units 812, 814, and 816 support a crystal growth apparatus 860. Other ratios, such as 2:1, 4:1, 5:1, or even a higher ratio can be used. In another embodiment, one deadsorption unit may be dedicated to two or more crystal growth apparatuses. FIG. 9 illustrates a 1:3 ratio, where one deadsorption unit 910 supports crystal growth apparatuses 962, 964, and 966. Other ratios, such as 1:2, 1:4, 1:5, or even a different ratio can be used. In a further embodiment, two or more deadsorption units can support two or more crystal growth apparatuses. FIG. 10 illustrates a 1:3 ratio, where three deadsorption units 1012, 1014, and 1016 support crystal growth apparatuses 1062, 1064, and 1066. The number of deadsorption units and crystal grown units can be different. Other ratios, such as 4:2, 3:4, 2:5, or even a different ratio can be used. Still further, different deadsorption units may support a different number of crystal growth apparatuses. For example, in an embodiment (not illustrated), the deadsorption unit 1012 may support the crystal growth apparatuses 1062 and 1064 but not the crystal growth apparatus 1066, and the deadsorption unit 1014 may support the crystal growth apparatuses 1062, 1064, and 1066. In yet a further embodiment, an intermediate container may be used to store deadsorbed material from a deadsorption unit before the deadsorbed material is fed to a crystal growth apparatus. FIG. 11 illustrates the deadsorption units 1112, 1114, and 1116 are coupled to an intermediate container 1142 that is coupled to crystal growth apparatuses 1162, 1164, and 1166. In other embodiment, a different number of deadsorption units, a different number of crystal growth apparatuses, or different numbers of deadsorption units and crystal growth apparatuses may be coupled to the intermediate container 1142. After reading this specification, skilled artisans will appreciate that different configurations can be used without departing from the scope of the concepts as described herein.

Attention is directed to methods of forming crystals using a crystal growth system. While the method is described mainly with respect to the crystal growth system as illustrated in FIGS. 1, 2, and 7, the method is applicable to other crystal growth systems. The crystal may be transparent, be a luminescent material, or the like. A luminescent material may be used for a scintillator, a laser diode, or the like.

The initial material selected depends upon the composition of the crystal. The crystal can be a metal oxide, a metal halide, or the like. Exemplary materials can include sapphire, alumina, a lutetium silicate, sodium iodide, lanthanum chloride, lanthanum bromide, an elpasolite, or another suitable material from which a crystal may be formed. The initial material may be of the same composition as the crystal or may be a constituent of the crystal. For example, for cerium-doped lutetium oxyorthosilicate (LuSiO₅:Ce), the initial material may be LuSiO₅:Ce, or it may be a combination of Lu₂O₃, SiO₂, and CeO₄. The constituents may be deadsorbed at the same time in the same deadsorption unit (such as deadsorption unit 110 in FIGS. 1 and 2) or may be deadsorbed in different deadsorption units (such as deadsorption units 812, 814, and 816 in FIG. 8). In another embodiment, the initial material may be of substantially the same crystalline structure as the crystal, such as crackle when forming sapphire, or may have a different crystalline structure as compared to the crystal, such as porous alumina when forming sapphire. The initial material can be in the form of particles.

The method is useful for all initial materials and is particularly well suited for porous starting materials that can have more area where impurities may adsorb. In an embodiment, the initial material has an open porosity of at least 0.01%, at least 0.02%, or at least 0.03%, and in another embodiment, the initial material has an open porosity no greater than 25%, no greater than 20%, or no greater than 15%. In a particular embodiment, the initial material has an open porosity in a range of at least 0.01% to 25%, 0.02% to 20%, or 0.03% to 15%. The deadsorption unit 100 may not be able to reduce impurities within closed pores. Initial material with less closed porosity, as opposed more closed porosity, may be used. Ideally, zero closed porosity may work best, but zero closed porosity may be hard to achieve. If the closed porosity is too high, the initial material may be crushed to reduced closed porosity. The crushing may be performed before the initial material reaches the deadsorption unit 100 or within the deadsorption unit. In an embodiment, the initial material has a closed porosity of at least 0.05%, at least 0.09%, or at least 0.13%, and in another embodiment, the initial material has a closed porosity no greater than 15%, no greater than 12%, or no greater than 9%. In a particular embodiment, the initial material has a closed porosity in a range of at least 0.05% to 15%, 0.09% to 12%, or 0.13% to 9%. The surface area per unit mass may depend on the particular material used. When the initial material includes alumina, in an embodiment, the alumina has a surface area of at least 0.005 m²/g, at least 0.007 m²/g, or at least 0.009 m²/g, and in another embodiment, the alumina has a surface area no greater than 5 m²/g, no greater than 2 m²/g, or no greater than 0.9 m²/g. In a particular embodiment, the alumina has a surface area in a range of at least 0.005 m²/g to 5 m²/g, 0.007 m²/g to 2 m²/g, or 0.009 m²/g to 0.9 m²/g.

The initial material can be fed into the deadsorption unit 100. Referring to FIG. 1, the transfer controller 138 opens the valve 151, and the initial material enters the deadsorption unit 110. In an embodiment, the transfer controller 138 closes the valve 151 after the deadsorption unit 110 is charged with the initial material. In another embodiment, the process can be operated in a continuous manner, and the valve 151 is opened only enough so that a desired or predetermined flow rate of initial material is achieved.

The deadsorption may be performed at different temperatures and pressure. The deadsorption can remove an impurity, such as O₂, H₂O, or the like that may be adsorbed to the surface. In other embodiments, the adsorbed impurities may also include N₂, CO₂, or the like. Deadsorption is more effective as pressure is reduced and temperature is increased.

With respect to pressure, the deadsorption can be performed at atmospheric pressure. In another embodiment, the deadsorption can be performed under vacuum. After the initial material is in the deadsorption unit 110, the deadsorption controller 118 can open valve 154, and a vacuum source (not illustrated) can evacuate the deadsorption chamber of the deadsorption unit 110. As the desired vacuum pressure decreases, more complicated equipment may be used for a vacuum source. For example, a diffusion pump or a cryogenic pump may be used for pressures at or less than 1×10⁻⁵ torr. A vacuum pump with or without a blower (for example, a Roots blower) may be able to achieve pressures from just below atmospheric pressure to 1×10⁻⁴ torr. In an embodiment, deadsorption is performed at a pressure of at least 1×10⁻⁸ torr, at least 1×10⁻⁶ torr, at least 1×10⁻⁵ torr, or at least 1×10⁻⁴ torr, and in another embodiment, deadsorption is performed at a pressure no greater than atmospheric pressure, no greater 10⁰ torr, no greater than 1 torr, or no greater than 0.1 torr. In a particular embodiment, deadsorption is performed at a pressure in a range of 1×10⁻⁸ torr to atmospheric pressure, 1×10⁻⁶ torr to 100 torr, 1×10⁻⁵ torr to 1 torr, or 1×10⁻⁴ torr to 0.1 torr.

With respect to temperature, the adsorption may be performed as low as −80° C., as freeze drying can be used to remove water. In many applications, the temperature will be higher than the atmospheric boiling point of an impurity to be removed. For example, water has a relatively high boiling point as compared to other adsorbed impurities. Thus, a temperature of 105° C. may be used for deadsorption. The temperature may not be so high that the initial material melts or starts to become plastic or sticky. Other considerations, such as equipment selection, may cause practical limits. For example, above 400° C., the selection of materials for the equipment may be limited. In an embodiment, the deadsorption is performed at a temperature of at least −80° C., at least 105° C., at least 150° C., or at least 200° C., and in another embodiment, the deadsorption is performed at a temperature no greater than 1200° C., no greater than 750° C., no greater than 500° C., or no greater than 400° C. In a particular embodiment, the deadsorption is performed at a temperature in a range of −80° C. to 1200° C., 105° C. to 750° C. %, or 150° C. to 500° C. When the deadsorption chamber is to be at a temperature higher than room temperature (20° C. to 25° C.), the deadsorption controller 118 controls the heater 230 (in FIG. 2) to provide sufficient heat. A temperature sensor (not illustrated) provides a signal to the deadsorption controller 118 to maintain the proper temperature. The deadsorption unit 110 may be heated before or after the initial material enters the deadsorption unit 110. When the deadsorption chamber is to be at a temperature lower than room temperature (20° C. to 25° C.), the deadsorption controller 118 controls a cooling unit (not illustrated) to provide sufficient cooling.

One or more deadsorbing gases can be introduced into the deadsorption chamber of the deadsorption unit 110. In an embodiment, the deadsorption can be performed with a deadsorbing gas that is an inert gas, such as a noble gas that may include Ar, He, or another Group 16 gas. In another embodiment, the deadsorption can be performed with a deadsorbing gas that includes H₂, CO, CO₂, or the like. The deadsorption gas is substantially free of the impurity that is to be deadsorbed. When O₂ and H₂O are to be deadsorbed from the initial material, the deadsorption gas has less than 0.1 vol. % of each of O₂ and H₂O, and in a particular embodiment, the deadsorption has less than 1 ppm by volume of each of O₂ and H₂O. In a further embodiment, a combination of the foregoing gases may be used. In a particular embodiment, Ar and H₂ can be used where H₂ is at a concentration below the lower explosive limit in air (less than 4% H₂). In another embodiment, particular gases may not be used, or if used, their concentrations are kept low. Although the feed system is operated as a sealed system, some air may leak into the system. In an embodiment, the deadsorbing gas has less than 2 vol. % O₂, less than 2 vol. % CO₂, less than 2 vol. % N₂ or less than 2 vol. % of a combination of O₂, CO₂, and N₂. With respect to CO₂, some crystal compositions may be adversely affected by CO₂, and other crystal compositions may not be adversely affected by CO₂. Thus CO₂ may or may not be used depending on the particular crystal composition. The deadsorbing gas may be heated before entering the deadsorption unit 110. The deadsorption controller 118 can send a signal to select the proper gas and adjust the flow rate of the gas through the valve 153. The deadsorption controller 118 can be coupled to a pressure sensor (not illustrated) that senses the pressure within the deadsorption unit and can adjust the flow of gas through a mass flow controller within the deadsorption gas source 116, the valve 153 or the valve 154.

In a further embodiment, deadsorption can be performed as one or more evacuate-and-backfill cycles. The deadsorption controller 118 can close all valves except valve 124 to achieve a desired vacuum pressure; optionally, allow a predetermined time to pass; and then close valve 124 and open valve 122 to repressurize the deadsorption chamber. This sequence can be repeated as needed or desired.

During deadsorption, impurities are removed from exposed surfaces of the initial material to form deadsorbed material. The deadsorbed material can be transferred from the deadsorption unit 110 to the crystal growth apparatus 160. During the transfer, the deadsorbed material goes from a lower elevation to a higher elevation. Thus, the feed system is not constrained to a particular layout as compared to a gravity feed system. The venturi device 140 can use a carrier gas to pull the deadsorbed material into the venturi device 140 and form a fluidized stream. The carrier gas may be any one or more gases described with respect to the deadsorbing gas. The carrier gas and the deadsorbing gas may be the same or different. A pressure differential between the venturi device 140 and the particle separator 130 Type equation here. causes the deadsorbed material to move from the venturi device 140, through the tube 142, and into the particle separator 130. In an embodiment, the deadsorbed material can be pushed by pressure from the carrier gas or may be pulled from a vacuum at a downstream location. For example, the carrier gas outlet line 134 from the particle separator 130 can be placed under vacuum to help to pull the fluidized stream into the particle separator 130. In a further embodiment, both positive pressure from the carrier gas and a downstream vacuum can be used.

The flow rate of the carrier gas can depend on the particle size and mass density of the deadsorbed material and the desired carrier gas velocity within the tube 142 and may depend on the geometries of the particles or the elevational difference between the lowest and highest points during the transfer operation. As the particle size increases, cross-sectional area of the tube 142, or elevational difference increases, the gas flow rate through the tube 142 will also increase. Regarding particle size of the deadsorbed material, the deadsorbed material will not be transferred if the particle size is too large for the allowable flow rate of the carrier gas or other considerations of the downstream equipment (for example, the maximum gas flow rating of the particle separator 130). Smaller particle sizes are easier to move; however, as the size gets smaller, the likelihood of clumping due to charge build up may be significant. In an embodiment, the median (D₅₀) particle size of the deadsorbed material may be at least 0.011 mm, at least 0.02 mm, or at least 0.05 mm, and in another embodiment, the D₅₀ particle size is no greater than 9.9 mm, no greater than 7 mm, or no greater than 5 mm. In a particular embodiment, the D₅₀ particle size is in a range of 0.011 mm to 9.9 mm, 0.02 mm to 7 mm, or 0.05 mm to 5 mm. The gas velocity can be determined by empirical studies or by simulations for a D₅₀ particle size and mass density of the deadsorbed material.

During the transfer from the deadsorbing unit, the deadsorption controller 118 closes valves 122 and 124, if they were not already closed, and the transfer controller 128 closes valve 156, if it was not already closed, and opens valves 152, 155, and 157. After the valves are in their proper positions, the transfer controller 128 can control the carrier gas flow rate within the carrier gas source 136, the vacuum pressure within the carrier gas outlet line 134 from the particle separator 130, or both. As the carrier gas passes through the venturi device 140, a localized area of relatively lower pressure is generated just downstream of the throat of the venturi device 140 and pulls the deadsorbed material from the material outlet line 114 into the venturi device 140. The carrier gas and deadsorbed material mix to create the fluidized stream. The pressure differential between the venturi device 140 and the particle separator 130 allows the fluidized stream, including the deadsorbed material, to flow through the tube 142 up to the particle separator 130. The elevational difference from the venturi device 140 to a highest point along the tube 142 or to the entry port to the particle separator 130 can be at least 2 cm, at least 5 cm, or at least 11 cm or may be no greater than 900 cm, no greater than 500 cm, or no greater than 200 cm. The elevational difference between the venturi device 140 and the entry port to the crystal growth apparatus 160 can be at least 2 cm, at least 5 cm, or at least 11 cm or may be no greater than 500 cm, no greater than 300 cm, or no greater than 90 cm.

In another embodiment, the crystal growth system can operate as a continuous operation. In this embodiment, the valve 156 may remain open during the transfer operation. The transfer controller 138 can adjust the valves to control the pressure within the particle separate to reduce the likelihood of adversely affecting crystal growth that may be occurring in the crystal growth apparatus 130 during the transfer.

In the particle separator 130, the fluidized stream can be separated into the deadsorbed material that can collect near the bottom and the carrier gas that can exit through the carrier gas outlet line 134. During the transfer, some smaller particles may be generated as the deadsorbed material comes in contact with the venturi device 140, inside of tube 142, particle separator 130, fittings, or other equipment. A mesh or other particle size separator may be used within or in conjunction with the particle separator 130 to separate the smaller particles from the deadsorbed material so that the smaller particles do not enter the crystal growth apparatus 160.

The deadsorbed material can pass through the particle outlet line 144 and into the crystal growth apparatus. The deadsorbed material can be melted in the crucible 710 in forming or replenishing the melt 720. The melt 720 can enter a capillary tube within the die 740 and form a meniscus 750 at the top of the die 740. A seed crystal can contact the meniscus, and the seed crystal can be pulled to form the crystal. In a particular embodiment, the crystal can be in the form of a sheet, as illustrated in FIG. 7, or may have a different shape.

The growth rate of a crystal may depend on the cross-sectional shape and size and crystal orientation of the crystal being formed, and the initial material used to form the crystal. For example, an as-grown crystal sheet can have a different growth rate as compared to a large boule, and the large boule may have a different growth rate as compared to an as-grown tube or fiber. Furthermore, different crystal orientations may affect the growth rate. For example, a sapphire sheet having major surfaces along A-planes may have a different growth rate as compared to a sapphire sheet having major surfaces along the C-planes. To remove variability due to these factors, the description below compares different crystals made with the same crystal growth technique, same cross-sectional shape and size and crystal orientation, and initial material.

The use of deadsorbed material can allow for higher crystal growth rates as compared to material that is not deadsorbed. Large sized crystals may have material added to the crucible while the crystal is being grown. The addition of material during the growth can increase the likelihood that haze will increase in the resultant crystal. Furthermore, haze decreases when the growth rate decreases. Haze can be determined a diffused transmission different in reference to a gold minor or as a diffused reflection difference to a gold mirror. In a particular embodiment, haze can be obtained using a Perkin-Elmer 950 Spectro-photometer (available from Perkin-Elmer, Inc. of Akron, Ohio, USA) and the testing methodology as set forth in ASTM D1003-11. Haze is expressed as the percentage of incident light that is scattered (scattered light/incident light×100%). The crystal can have a haze no greater than 0.20%, no greater than 0.18%, or no greater than 0.16%.

The inventors have discovered that using deadsorbed material can help to increase the crystal growth rate within an increase in the level of haze. The improvement may occur for a variety of initial materials. With respect to sapphire, crackle is considered the best commercial source to make a sapphire crystal. Even with crackle, the growth rate can be increased without an increase in haze. The methods described herein are more beneficial as the initial material has more surface area and less closed porosity. In an embodiment, a crystal formed from deadsorbed material can be grown at least 1.1 times, at least 1.2 times, at least 1.3 times, or at least 1.4 times the growth rate of a crystal formed from the same material that is not deadsorbed. The growth rate increase may be limited by other consideration. In another embodiment, a crystal formed from deadsorbed material can be grown no greater than 9 times, no greater 7 times, no greater than 5 times, or no greater than 3 times the growth rate of a crystal formed from the same material that is not deadsorbed. In a particular embodiment, a crystal formed from deadsorbed material can be grown in a range of 1.1 times to 9 times, 1.2 times to 7 times, 1.3 times to 5 times, or 1.4 times to 3 times the growth rate of a crystal formed from the same material that is not deadsorbed. Thus, the crystal can be formed from deadsorbed material at a faster growth rate without an increase in haze level as compared to the crystal formed from the initial material without being deadsorbed. In a particular embodiment, the haze level can be determined by a product specification limit (for example, haze not to exceed 0.15%.)

The concepts as described herein can also help to maintain a more constant volume of melt within the crucible 730. The volume control may be expressed in terms of volume variation for a particular percentage of crystal formed. A crystal is formed from a seed that transitions in the neck to a main body. In an embodiment, transferring of the crystal-forming material is performed continuously to keep a melt in the crucible from varying by no more than 20%, no more than 15%, no more than 12%, or no more than 9% during at least 20% of the growth of a main body of the crystal, and in another embodiment, transferring of the crystal forming material is performed continuously and a melt in the crucible varies by at least 0.0001% during at least 20% of the growth of a main body of the crystal. The volume control may be expressed in terms of a percentage growth over which a volume variation does not exceed a particular amount. In an embodiment, wherein transferring of the crystal-forming material is performed continuously to keep a melt in the crucible from varying by no more than 20%, during at least 30%, at least 40%, or at least 50% of the growth of a main body of the crystal, and in another embodiment, transferring of the crystal-forming material is performed continuously to keep a melt in the crucible from varying by no more than 20%, during no greater than 99%, no greater than 96% or no greater than 93%, or no greater than 90% of the growth of a main body of crystal. In a particular embodiment, transferring of the crystal-forming material is performed continuously to keep a melt in the crucible from varying by no more than 20%, during 20% to 99%, 30% to 96%, 40% to 93%, or 50% to 90% of the growth of a main body of the crystal.

In another embodiment, a different configuration of controllers may be used. For example, any one or more of the functions are described with respect to the deadsorption controller 118 may be performed by the transfer controller 138, and any one or more of the functions are described with respect to the transfer controller 138 may be performed by the deadsorption controller 118. In a further embodiment, the functions of the deadsorption and transfer controllers 118 and 138 may be combined into a single controller. In a further embodiment, the controllers 118 and 138 may be in a master/slave configuration with each other or another controller. For example, the crystal growth apparatus 160 may have a controller that is a master controller over the controllers 118 and 138. After reading this specification, skilled artisans will appreciate that the arrangement and functions of the controllers can be adapted for a particular application.

Embodiments in accordance with the embodiments described herein can allow for crystals to be formed as higher growth rates without an increase in haze. In an embodiment, initial material is deadsorbed before such material enters a crucible of a crystal growth apparatus. In a particular embodiment, a crystal growth system can be configured to allow a continuous feed of the crystal-forming material to allow the volume within the crucible to be controlled to a more constant level. The benefits can be significant for when the crystal has a relatively thin thickness, such as for thin crystal sheets or tubes. Thus, the increase in production of crystals can occur without a decrease in yield.

Many different aspects and embodiments are possible. Some of those aspects and embodiments are described herein. After reading this specification, skilled artisans will appreciate that those aspects and embodiments are only illustrative and do not limit the scope of the present invention. Embodiments may be in accordance with any one or more of the embodiments as listed below.

### Embodiment 1

A feed system for a crystal growth apparatus comprising:
a deadsorption unit to deadsorb an impurity from a material used to form a crystal; and
a tube adapted to be fluidly coupled to the deadsorption unit and the crystal growth apparatus to transfer the material from a first point at a first elevation to a second point at a second elevation higher than the first elevation, wherein along a fluid path:
   the deadsorption unit is adapted to be closer to the first point than to the second point; and
   the crystal growth apparatus is adapted to be closer to the second point than to the first point.

### Embodiment 2

A feed system for a crystal growth apparatus comprising:
deadsorption units to deadsorb an impurity from a material used to form a crystal; and
at least one tube adapted to be fluidly coupled to the deadsorption units and the crystal growth apparatus to transfer the material from a selected deadsorption unit of the deadsorption units to the crystal growth apparatus.

### Embodiment 3

A crystal growth system comprising:
the feed system of Embodiment 1 or 2; and
a crystal growth apparatus coupled to the feed system.

### Embodiment 4

A feed system for crystal growth apparatuses comprising:
a deadsorption unit to deadsorb an impurity from a material used to form a crystal; and
at least one tube adapted to be fluidly selectively coupled to the deadsorption unit to transfer the material from the deadsorption unit to a selected crystal growth apparatus to the crystal growth apparatuses.

### Embodiment 5

A feed system for crystal growth apparatuses comprising:
deadsorption units to deadsorb an impurity from a material used to form a crystal; and
at least one tube adapted to be fluidly coupled to the deadsorption units to transfer the material from a selected deadsorption unit of the deadsorption units to a selected crystal growth apparatus to the crystal growth apparatuses.

### Embodiment 6

A crystal growth system comprising:
the feed system of Embodiment 4 or 5; and
the crystal growth apparatuses, each of which is coupled to the feed system.

### Embodiment 7

A method comprising:
providing a crystal growth system of any one of Embodiments 1 to 6;
deadsorbing the impurity from an initial material to form a deadsorbed material; and
growing a crystal from the deadsorbed material.

### Embodiment 8

The method of Embodiment 7, wherein deadsorbing is performed at a temperature of at least −80° C., at least 105° C., at least 150° C., or at least 200° C.

### Embodiment 9

The method of Embodiment 7 or 8, wherein deadsorbing is performed at a temperature no greater than 1200° C., no greater than 750° C., no greater than 500° C., or no greater than 400° C.

### Embodiment 10

The method of any one of Embodiments 7 to 9, wherein deadsorbing is performed at a temperature in a range of −80° C. to 1200° C., 105° C. to 750° C., or 150° C. to 500° C.

### Embodiment 11

The method of any one of Embodiments 7 to 10, wherein deadsorbing is performed at a pressure of at least 1×10⁻⁸ torr, at least 1×10⁻⁶ torr, at least 1×10⁻⁵ torr, or at least 1×10⁻⁴ torr.

### Embodiment 12

The method of any one of Embodiments 7 to 11, wherein deadsorbing is performed at a pressure no greater than atmospheric pressure, no greater than 100 torr, no greater than 1 torr, or no greater than 0.1 torr.

### Embodiment 13

The method of any one of Embodiments 7 to 12, wherein deadsorbing is performed at a pressure in a range of 1×10⁻⁸ torr to atmospheric pressure, 1×10⁻⁶ torr to 100 torr, 1×10⁻⁵ torr to 1 torr, or 1×10⁻⁴ torr to 0.1 torr.

### Embodiment 14

The method of any one of Embodiments 7 to 13, wherein deadsorbing is performed during at least 2 evacuate-and-backfill cycles.

### Embodiment 15

The method of any one of Embodiments 7 to 14, wherein deadsorbing is performed for a time of at least 2 minutes, at least 5 minutes, at least 11 minutes, or at least 20 minutes.

### Embodiment 16

The method of any one of Embodiments 7 to 15, wherein deadsorbing is performed for a time no greater than 48 hours, no greater 24 hours, no greater than 9 hours, or no greater than 2 hours.

### Embodiment 17

The method of any one of Embodiments 7 to 16, wherein deadsorbing is performed at a pressure in a range of 2 minutes to 48 hours, 5 minutes to 24 hours, 11 minutes to 9 hours, or 20 minutes to 2 hours.

### Embodiment 18

The method of any one of Embodiments 7 to 17, wherein deadsorbing is performed using a deadsorbing gas that includes a noble gas, H₂, CO, CO₂, or any combination thereof.

### Embodiment 19

The method of any one of Embodiments 7 to 18, wherein the deadsorbing gas has less than 2 vol. % O₂.

### Embodiment 20

The method of any one of Embodiments 7 to 19, wherein the deadsorbing gas has less than 2 vol. % CO₂.

### Embodiment 21

The method of any one of Embodiments 7 to 20, wherein the deadsorbing gas has less than 2 vol. % N₂.

### Embodiment 22

The method of any one of Embodiments 7 to 21, further comprising transferring the deadsorbed material as a fluidized stream through the tube.

### Embodiment 23

The method of Embodiment 22, wherein the fluidized stream includes a carrier gas.

### Embodiment 24

The method of Embodiment 22 to 23, wherein the carrier gas that includes a noble gas, H₂, CO, CO₂, or any combination thereof.

### Embodiment 25

The method of any one of Embodiments 22 to 24, wherein the carrier gas has less than 2 vol. % O₂.

### Embodiment 26

The method of any one of Embodiments 22 to 25, wherein the carrier gas has less than 2 vol. % CO₂.

### Embodiment 27

The method of any one of Embodiments 22 to 26, wherein the carrier gas has less than 2 vol. % N₂.

### Embodiment 28

The method of any one of Embodiments 22 to 27, further comprising separating the deadsorbed particles from the fluidized stream before the deadsorbed particles are introduced into a crucible within a crystal growth apparatus.

### Embodiment 29

The method of any one of Embodiments 7 to 28, wherein deadsorbing is performed in a deadsorption unit.

### Embodiment 30

The method of any one of Embodiments 7 to 29, wherein growing the crystal is performed in a crystal growth apparatus.

### Embodiment 31

The feed system, the crystal growth system, or the method of any one of the preceding Embodiments, wherein the deadsorption unit comprises an inlet to receive the deadsorbing gas and an outlet coupled to a vacuum system.

### Embodiment 32

The feed system, the crystal growth system, or the method of any one of the preceding Embodiments, wherein the deadsorption unit comprises a feed inlet to receive the material.

### Embodiment 33

The feed system, the crystal growth system, or the method of Embodiment 32, wherein the deadsorption unit is adapted to receive a continuous feed of the material.

### Embodiment 34

The feed system, the crystal growth system, or the method of any one of the preceding Embodiments, wherein the deadsorption unit comprises a flow distributor to distribute a flow of a deadsorbing gas before reaching the material.

### Embodiment 35

The feed system, the crystal growth system, or the method of any one of the preceding Embodiments, wherein the deadsorption unit comprises a heater to heat a deadsorption chamber.

### Embodiment 36

The feed system, the crystal growth system, or the method of any one of the preceding Embodiments, wherein the feed system further comprises a heater to heat a deadsorbing gas before entering the deadsorption chamber.

### Embodiment 37

The feed system, the crystal growth system, or the method of any one of Embodiments 1 to 34, wherein the deadsorption unit comprises a cooling unit to cool a deadsorption chamber.

### Embodiment 38

The feed system, the crystal growth system, or the method of any one of Embodiments 1 to 34 and 35, wherein the feed system further comprises a cooling unit to cool a deadsorbing gas before entering the deadsorption chamber.

### Embodiment 39

The feed system, the crystal growth system, or the method of any one of the preceding Embodiments, further comprising a gas source coupled to the tube, wherein the gas source is adapted to provide a carrier gas to the tube.

### Embodiment 40

The feed system, the crystal growth system, or the method of any one of Embodiments 1 to 38, further comprising a vacuum source coupled to the tube, wherein the vacuum source is adapted to pull a carrier gas into the tube.

### Embodiment 41

The feed system, the crystal growth system, or the method of any one of the preceding Embodiments, further comprising a venturi valve or a venturi eductor coupled to the tube, wherein the venturi valve or the venturi eductor is to regulate the amount of material entering into the tube.

### Embodiment 42

The feed system, the crystal growth system, or the method of Embodiment 38, wherein the venturi valve or venturi eductor is located downstream of the gas source or between the deadsorption unit and the crystal growth apparatus.

### Embodiment 43

The feed system, the crystal growth system, or the method of any one of the preceding Embodiments, further comprising a particle separator to separate a carrier gas from the material before entering a crucible of the crystal growth apparatus.

### Embodiment 44

The feed system, the crystal growth system, or the method of any one of the preceding Embodiments, further comprising an intermediate container coupled to the deadsorbing unit and crystal growth apparatus.

### Embodiment 45

The feed system, the crystal growth system, or the method of any one of the preceding Embodiments, further comprising an intermediate container coupled to at least two deadsorbing units, at least two crystal growth apparatuses, or to at least two deadsorbing units and at least two crystal growth apparatuses.

### Embodiment 46

The feed system, the crystal growth system, or the method of any one of the preceding Embodiments, wherein the feed system is a sealed system at least from the deadsorbing unit to the crystal growth apparatus.

### Embodiment 47

The feed system, the crystal growth system, or the method of any one of the preceding Embodiments, wherein the crystal growth apparatus is a Czochralski growth apparatus, a Kyropolous growth apparatus, a Bridgman growth apparatus, or Vertical Gradient Freeze (VGF) apparatus.

### Embodiment 48

The feed system, the crystal growth system, or the method of any one of Embodiments 1 to 46, wherein the crystal growth apparatus is a Stepanov growth apparatus or an edge-defined film-fed growth (EFG) apparatus.

### Embodiment 49

The feed system, the crystal growth system, or the method of any one of the preceding Embodiments, further comprising a control module to control the flow of material to the crystal growth apparatus.

### Embodiment 50

The feed system, the crystal growth system, or the method of any one of the preceding Embodiments, further comprising a control module to select:
a particular deadsorbing unit of the deadsorption units that is to provide the material to the crystal growth apparatus;
a particular crystal growth apparatus of the crystal growth apparatuses that is to receive the material to the deadsorption unit; or
a particular deadsorbing unit of the deadsorption units that is to provide the material to a particular crystal growth apparatus of the crystal growth apparatuses.

### Embodiment 51

The feed system, the crystal growth system, or the method of any one of the preceding Embodiments, wherein the material is a metal oxide.

### Embodiment 52

The feed system, the crystal growth system, or the method of any one of the preceding Embodiments, wherein the material consists essentially of alumina, and the crystal grown apparatus is adapted to form sapphire.

### Embodiment 53

The feed system, the crystal growth system, or the method of any one of the preceding Embodiments, material is a metal halide.

### Embodiment 54

The feed system, the crystal growth system, or the method of any one of Embodiments 1 to 48 and 50, wherein the material is a luminescent material.

Note that not all of the activities described above in the general description or the examples are required, that a portion of a specific activity may not be required, and that one or more further activities may be performed in addition to those described. Still further, the order in which activities are listed is not necessarily the order in which they are performed.

Certain features that are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges includes each and every value within that range.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. A feed system for a crystal growth apparatus comprising:
a deadsorption unit to deadsorb an impurity from a material used to form a crystal; and
a tube adapted to be fluidly coupled to the deadsorption unit and the crystal growth apparatus to transfer the material from a first point at a first elevation to a second point at a second elevation higher than the first elevation, wherein along a fluid path:
the deadsorption unit is adapted to be closer to the first point than to the second point; and
the crystal growth apparatus is adapted to be closer to the second point than to the first point.

2. The feed system of claim 1, further comprising a venturi valve or a venturi eductor coupled to the tube, wherein the venturi valve or the venturi eductor is to regulate the amount of material entering into the tube.

3. The feed system of claim 2, wherein the venturi valve or venturi eductor is located downstream of the gas source or between the deadsorption unit and the crystal growth apparatus.

4. The feed system of claim 1, further comprising a particle separator to separate a carrier gas from the material before entering a crucible of the crystal growth apparatus.

5. A crystal growth system comprising:
at least one deadsorption unit to deadsorb an impurity from a material used to form a crystal;
at least one crystal growth apparatus; and
at least one tube adapted to be fluidly coupled to the at least one deadsorption unit to transfer the material from the at least one deadsorption unit to the at least one crystal growth apparatus,
wherein:
the at least one deadsorption unit includes at least two deadsorption units;
the at least one crystal growth apparatus includes at least two crystal growth apparatuses; or
the at least one deadsorption unit includes at least two deadsorption units, and the at least one crystal growth apparatus includes at least two crystal growth apparatuses.

6. A method comprising:
providing a crystal growth system comprising a deadsorption unit, a crystal growth apparatus, and a tube fluidly coupled to the deadsorption unit and the crystal growth apparatus, wherein the tube adapted is fluidly coupled to the deadsorption unit and the crystal growth apparatus;
deadsorbing the impurity from an initial material to form a deadsorbed material;
transferring the deadsorbed material through the tube from a first point at a first elevation to a second point at a second elevation higher than the first elevation, wherein along a fluid path, the deadsorption unit is closer to the first point than to the second point, and the crystal growth apparatus is closer to the second point than to the first point; and
growing a crystal from the deadsorbed material.

7. The method of claim 6, wherein deadsorbing is performed at a pressure no greater than atmospheric pressure.

8. The method of claim 6, wherein deadsorbing is performed during at least 2 evacuate-and-backfill cycles.

9. The method of claim 6, wherein deadsorbing is performed using a deadsorbing gas that includes a noble gas, H₂, CO, CO₂, or any combination thereof.

10. The method of claim 9, wherein the deadsorbing gas has less than 2 vol. % O₂, less than 2 vol. % CO₂, or less than 2 vol. % N₂.

11. The method of claim 6, further comprising transferring the deadsorbed material as a fluidized stream through the tube, wherein the fluidized stream includes a carrier gas that includes a noble gas, H₂, CO, CO₂, or any combination thereof.

12. The method of claim 11, wherein the carrier gas has less than 2 vol. % O₂, less than 2 vol. % CO₂, or less than 2 vol. % N₂.

13. The method of claim 11, further comprising separating the deadsorbed particles from the fluidized stream before the deadsorbed particles are introduced into a crucible within a crystal growth apparatus.

14. The method of claim 6, wherein the deadsorption unit comprises a feed inlet to receive the material.

15. The method of claim 14, wherein the deadsorption unit is receives a continuous feed of the material.

16. The method of claim 6, further comprising a venturi valve or a venturi eductor coupled to the tube, wherein the venturi valve or the venturi eductor is to regulate the amount of material entering into the tube.

17. The method of claim 16, wherein the venturi valve or venturi eductor is located downstream of the gas source or between the deadsorption unit and the crystal growth apparatus.

18. The method of claim 6, wherein the material is a metal oxide.

19. The method of claim 6, wherein the material consists essentially of alumina, and the crystal grown apparatus is adapted to form sapphire.

20. The method of claim 6, wherein the initial material is a metal halide.
